(19) United States
(12) Patent Application Publication
(10) Pub. No.: US 2026/0285045 A1
(43) Pub. Date: Sep. 24, 2026

(54) MAINTENANCE SYSTEM FOR INKJET HEADS AND ELECTRONIC APPARATUS

(71) Applicant: Samsung Display Co., LTD., Yongin-si (KR)

(72) Inventors: JAESIK KIM, Yongin-si (KR); JUNGHAN SEO, Yongin-si (KR); WOO YONG SUNG, Yongin-si (KR); SEUNGHO YOON, Yongin-si (KR); BYEONGJUN LEE, Yongin-si (KR); SEUNGYONG SONG, Yongin-si (KR)

(21) Appl. No.: 19/386,720

(22) Filed: Nov. 12, 2025

(30) Foreign Application Priority Data
Mar. 18, 2025 (KR) 10-2025-0034561

(51) Int. Cl. B41J 2/165; G06F 3/14; H05K 5/02

(52) U.S. Cl. CPC B41J 2/16544; B41J 2/16579; G06F 3/14; H05K 5/02; B41J 2002/1655; B41J 2002/16573; B41P 2235/246

(57) ABSTRACT

A maintenance system for inkjet heads includes, a wiper which absorbs residual ink remaining on the inkjet heads, a plurality of blotters which presses the wiper against the nozzles surfaces, and the controller which periodically performs individual position compensation of the plurality of blotters based on wear deviations of the coating films. The maintenance system for the inkjet heads performs the position compensation of the plurality of blotters based on an image obtained from a first sensor which acquires an image of coating films on the nozzle surfaces of the inkjet heads or a second sensor which acquires an image of the wiper.

### CROSS REFERENCE TO RELATED APPLICATIONS

This application claims priority to Korean Patent Application 10-2025-0034561, filed on Mar. 18, 2025, and all the benefits accruing therefrom under 35 U.S.C. §119, the content of which in its entirety is herein incorporated by reference.

### BACKGROUND

### 1. Field

The present disclosure relates to a maintenance system for the inkjet heads and an electronic apparatus. More specifically, the present disclosure relates to a maintenance system for the inkjet heads used in a manufacture of a display device.

### 2. Description of the Related Art

With the development of information technology, the importance of display devices as a medium connecting users and information is increasing. As a result, the use of display devices such as a liquid crystal display device (“LCD”), an organic light emitting display device (“OLED”), and a plasma display device (“PDP”) is increasing.

An inkjet head may form various layers included in the display device by discharging ink onto a substrate. After ejecting the ink from the inkjet head, residual ink may remain on a nozzle surface of the inkjet head. If the residual ink on the nozzle surface is not removed, the residual ink may cause a change in a discharge trajectory of the ink and/or clog a nozzle hole for ejecting the ink in a subsequent process, due to the residual ink. Accordingly, the maintenance system may remove the residual ink through the blotting process after an inkjet process.

### SUMMARY

Embodiments provide a maintenance system for inkjet heads with an improved service life.

Other embodiments provide an electronic apparatus manufactured using an inkjet head that is maintained by the maintenance system for the inkjet heads.

However, embodiments of the disclosure are not limited thereto, and may be expanded in various ways without departing from the spirit and scope of the disclosure.

A maintenance system for inkjet heads according to embodiments of the disclosure includes a first sensor which acquires an image of coating films on nozzle surfaces of the inkjet heads, a wiper which absorbs residual ink remaining on the inkjet heads, a plurality of blotters which presses the wiper against the nozzle surfaces, and a controller which periodically performs position compensation of the plurality of blotters based on wear deviations of the coating films.

In an embodiment, the plurality of blotters may have a predetermined offset from respective positions before the position compensation.

In an embodiment, a first coating film of a first head among the coating films of the inkjet heads may have the least wear, a first blotter among the plurality of blotters may press the wiper against a first nozzle surface of the first head, and the position compensation of the blotters may be performed based on the position of the first blotter.

In an embodiment, a first coating film of a first head among the coating films of the inkjet heads may have the least wear, the first coating film may include a first first portion having relatively less wear and a second first portion having relatively greater wear than the first first portion, a first blotter among the plurality of blotters may press the first nozzle surface of the first head against the wiper, a first portion of the first blotter may press the wiper against the first first portion of the first coating film, and a second portion of the first blotter may press the wiper against the second first portion of the first coating film, and the position compensation of the plurality of blotters may be performed based on the position of the first portion of the first blotter.

In an embodiment, the position compensation of the plurality of blotters may be performed in a direction to reduce the wear deviations of the coating films.

In an embodiment, the direction to reduce the wear deviations may correspond to a direction in which a gap between the plurality of blotters and the plurality of inkjet heads increases.

In an embodiment, the residual ink may include quantum dot particles.

In an embodiment, the controller may match speeds, heights, and tilt values of the plurality of blotters with the wear deviations to predict a cycle for position compensation of the plurality of blotters.

In an embodiment, the controller may match speeds, heights, and tilt values of the plurality of blotters with the wear deviations to predict a replacement cycle of a head pack that includes the plurality of inkjet heads.

A maintenance system for inkjet heads according to embodiments of the disclosure includes a wiper which absorbs residual ink remaining on the inkjet heads; a plurality of blotters which presses the wiper against nozzle surfaces of the inkjet heads; a second sensor which acquires an image of the wiper; and the controller which periodically performs position compensation of the plurality of blotters based on deviations in an amount of ink absorbed by the wiper.

In an embodiment, the plurality of blotters may have a predetermined offset from respective positions before the position compensation.

In an embodiment, a first head among the inkjet heads may have the smallest amount of residual ink absorbed by the wiper, a first blotter among the plurality of blotters may press the wiper against a first nozzle surface of the first head, and the position compensation of the plurality of blotters may be performed based on the position of the first blotter.

In an embodiment, a first head among the inkjet heads may have the smallest amount of residual ink absorbed by the wiper, the first head may include a first first portion having relatively less residual ink and a second first portion having relatively greater residual ink than the first first portion, a first blotter among a plurality of blotters may press the first nozzle surface of the first head against the wiper, a first portion of the first blotter may press the wiper against the first first portion of the first head, and a second portion of the first blotter may press the wiper against the second first portion of the first head, and the position compensation of the plurality of blotters may be performed based on the position of the first portion of the first blotter.

In an embodiment, the position compensation of the plurality of blotters may be performed in a direction to reduce an amount of residual ink absorbed by the wiper.

In an embodiment, the direction to reduce the amount of residual ink absorbed by the wiper may correspond to a direction in which a gap between the plurality of blotters and the plurality of inkjet heads increases.

In an embodiment, the residual ink may include quantum dot particles.

In an embodiment, the controller may match speeds, heights, and tilt values of the plurality of blotters with an amount of residual ink absorbed by the wiper to predict a cycle for position compensation of the plurality of blotters.

In an embodiment, the controller may match speeds, heights, and tilt values of the plurality of blotters with an amount of residual ink absorbed by the wiper to predict a replacement cycle of a head pack that includes the plurality of inkjet heads.

An electronic apparatus according to an embodiment of the disclosure includes a display device which displays an image and includes a substrate and a pattern formed on the substrate by inkjet heads; and a processor which transmits an image data signal and an input control signal to the display device, the inkjet heads are maintained by a maintenance system for the inkjet heads, where maintenance system for the inkjet heads includes: a wiper which absorbs residual ink remaining on nozzle surfaces of the inkjet heads; a plurality of blotters which presses the wiper against the nozzle surfaces; and a controller which periodically performs position compensation of the plurality of blotters in a direction to reduce a gap deviation between the plurality of inkjet heads and the plurality of blotters.

In an embodiment, the maintenance system may further include at least one selected from a first sensor which acquires an image of coating films on the nozzle surfaces of the inkjet heads and a second sensor which acquires an image of the wiper, and the controller may adjust a gap between the plurality of inkjet heads and the plurality of blotters based on at least one selected from the image of the coating films on the nozzle surfaces of the inkjet heads and the image of the wiper.

The maintenance system for the inkjet heads according to embodiments of the disclosure may include a first sensor which acquires an image of the coating films on the nozzle surfaces of the inkjet heads, a wiper which absorbs the residual ink remaining on the inkjet heads, a plurality of blotters which presses the wiper against the nozzle surfaces, and a controller which periodically performs position compensation of the plurality of blotters based on the wear deviations of the coating films. In such embodiments, the gaps between a plurality of inkjet heads and a plurality of blotters may vary. A deviation in the damage inflicted (e.g., peeling of the coating film on the nozzle surfaces of a plurality of inkjet heads) may occur due to the deviation in the gaps. The system may compensate the positions of the blotters based on a blotter corresponding to an inkjet head that has received the least damage. Thus, the wear deviations of the plurality of inkjet heads may be reduced, and the lifetime of a head pack including a plurality of inkjet heads may be improved.

The maintenance system for the inkjet heads according to embodiments of the disclosure may include the wiper which absorbs residual ink remaining on the inkjet heads, a plurality of blotters which presses the wiper against the nozzle surfaces of the inkjet heads, the second sensor which acquires an image of the wiper, and the controller which periodically performs position compensation of the plurality of blotters based on deviations in an amount of ink absorbed by the wiper. According to deviations in gaps between a plurality of inkjet heads and a plurality of blotters, a deviation in damage applied to a plurality of heads may occur. The greater the damage, the more nozzle surfaces lose their water-repellency and become more hydrophilic, resulting in an increase in the amount of residual ink remaining on the plurality of inkjet heads (i.e., the amount of residual ink). Accordingly, the amount of residual ink absorbed by the wiper may increase. in such embodiments, the controller may compensate the positions of the blotters based on a portion where the least amount of residual ink is absorbed by the wiper. Accordingly, the damage to the inkjet heads may be reduced. Accordingly, the wear deviations of a plurality of inkjet heads may be reduced, and the lifetime of a head pack including the plurality of inkjet heads may be improved.

However, the effect of the disclosure is not limited to the aforementioned effect, and it may be expanded in various ways without deviating from the idea and scope of the disclosure.

### BRIEF DESCRIPTION OF THE DRAWINGS

The above and other features of embodiments of the disclosure will become more apparent by describing in further detail embodiments thereof with reference to the accompanying views, in which:

FIG. 1 is a view illustrating a maintenance system for inkjet heads according to embodiments of the disclosure.

FIGS. 2, 3, 4, 5 and 6 are views illustrating an embodiment of a maintenance method for the inkjet heads using the maintenance system for the inkjet heads of FIG. 1.

FIG. 7 is a view illustrating a first sensor included in the maintenance system for the inkjet heads of FIG. 1.

FIG. 8 is a view illustrating the first image acquired by the first sensor of FIG. 7.

FIG. 9 is a view illustrating an embodiment of an operation of the controller included in the maintenance system for the inkjet heads of FIG. 1.

FIGS. 10 and 11 are views illustrating an embodiment of the position compensation of the plurality of blotters by the controller of FIG. 9.

FIG. 12 is a view illustrating an embodiment of a signal that forms a basis for the operation of the controller of FIG. 9.

FIGS. 13 and 14 are views illustrating embodiments of the operation of the controller included in the maintenance system for the inkjet heads of FIG. 1.

FIGS. 15 and 16 are images that serve as a basis for the operation of the controller of FIG. 1.

FIG. 17 is a view illustrating the position compensation of the blotter based on the images of FIGS. 15 and 16.

FIG. 18 shows the blotter after performing the position compensation of FIG. 17.

FIGS. 19 and 20 are images illustrating effects of the maintenance system for the inkjet head of FIG. 1.

FIG. 21 is a view illustrating a second sensor included in the maintenance system for the inkjet heads of FIG. 1.

FIG. 22 is a view illustrating an embodiment of the operation of the controller included in the maintenance system for the inkjet heads of FIG. 1.

FIG. 23 is a view illustrating an image acquired by the second sensor of FIG. 21.

FIG. 24 is a view illustrating an embodiment of the position compensation of the plurality of blotters based on the image of FIG. 23.

FIG. 25 is a view illustrating an inkjet head that is maintained by the maintenance system for the inkjet heads of the disclosure.

FIG. 26 is a view illustrating ink ejected by the inkjet heads of FIG. 25.

FIG. 27 is a block diagram of electronic devices according to an embodiment.

FIG. 28 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in greater detail with reference to the accompanying views. Same reference numerals will be used for the same components in the views, and any repetitive detailed descriptions of the same components will be omitted or simplified.

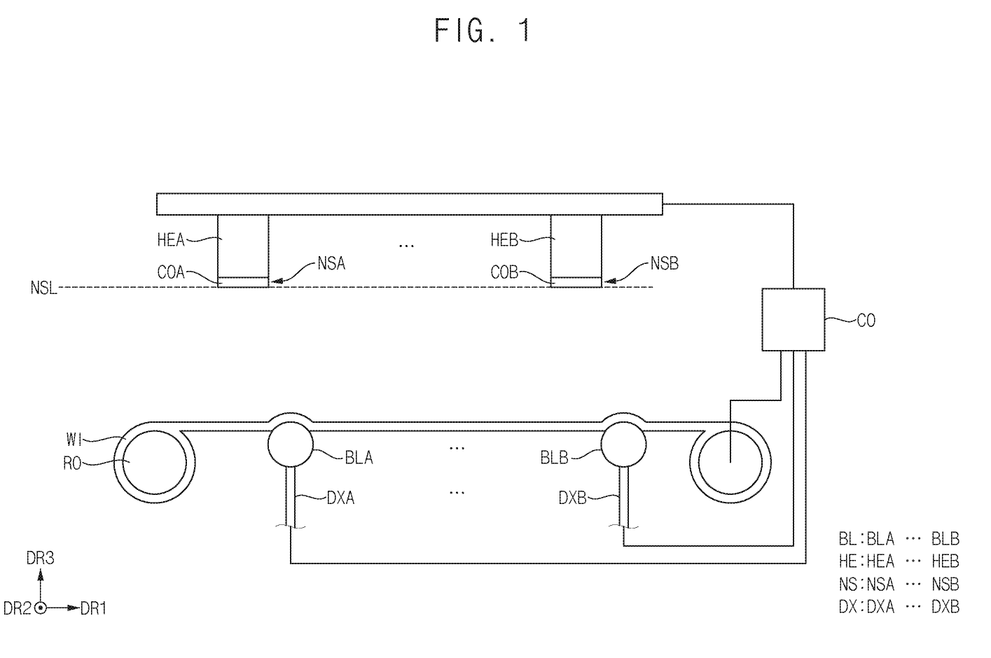

FIG. 1 is a view illustrating a maintenance system for inkjet heads according to embodiments of the disclosure.

Referring to FIG. 1, the maintenance system for the inkjet heads according to embodiments of the disclosure may be a system configured to perform a blotting process to clean a head pack including a plurality of inkjet heads HE.

The plurality of inkjet heads HE may be configured to perform an inkjet process in which ink is ejected onto a substrate to form various layers. After residual ink may remain on nozzle surfaces NS of the plurality of inkjet heads HE (hereinafter referred to as ‘residual ink’).

The blotting process may refer to a process of wiping off the residual ink on the nozzle surface NS. As the blotting process is repeated, the coating films (e.g., a first coating film COA, a second coating film COB, or the like) on the nozzle surfaces NS may be increasingly worn due to physical friction. The wear may cause a defective discharge such as a satellite. Here, the satellite may refer to a phenomenon in which the ink is splashed into an unintended area by the residual ink.

In an embodiment, for example, the head pack may include the plurality of inkjet heads HE. In an embodiment, for example, one head pack may include five heads HE. If damage (e.g., the wear) occurs in two or more of the five heads HE, the entire head pack may be desired to be replaced in consideration of tack time, or the like. The maintenance system for the inkjet heads according to embodiments of the disclosure may improve the service life of the head pack by minimizing the damage caused by the blotting process.

The maintenance system for the inkjet heads according to embodiments of the disclosure may include a plurality of blotters BL, a wiper WI, a plurality of drive axes DX, and a controller CO.

In an embodiment, the plurality of blotters BL may be positioned side by side in a first direction DR1. In an embodiment, for example, the plurality of blotters BL may include a first blotter BLA and a second blotter BLB that are spaced apart in the first direction DR1.

In an embodiment, the plurality of blotters BL may press the wiper WI against the nozzle surfaces NS. In an embodiment, for example, the plurality of blotters BL may include rubber, silicone, sponge, or the like. However, the disclosure is not limited thereto. In another embodiment, for example, the blotters BL may include or be made of any material that can press the wiper WI against the nozzle surfaces NS without restriction.

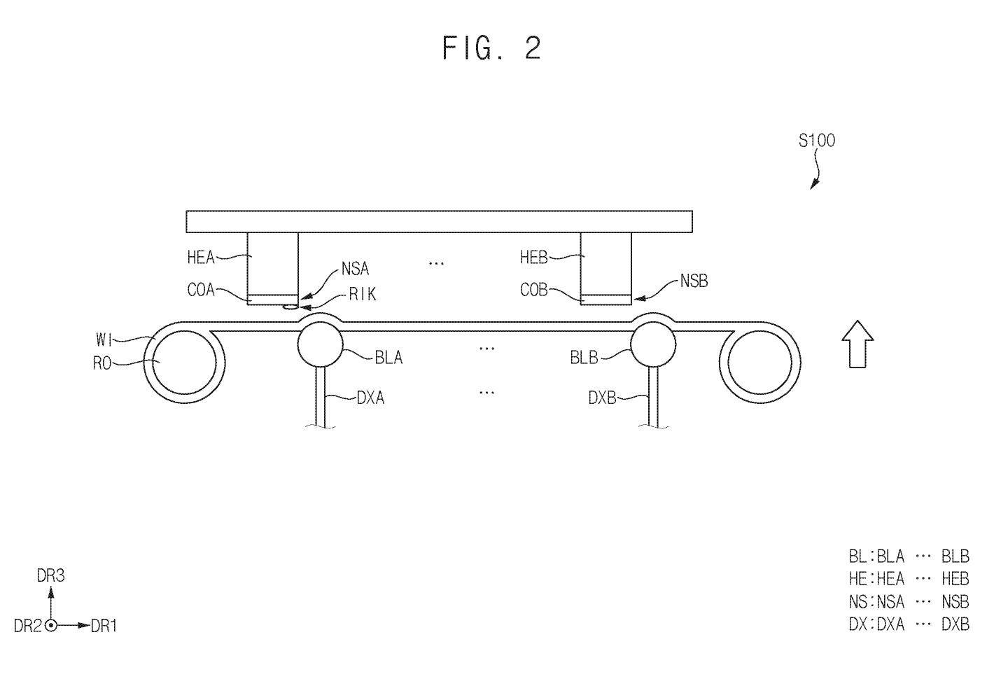

In an embodiment, the wiper WI may be positioned on the plurality of blotters BL. The wiper WI may absorb (remove) the residual ink (e.g., RIK of FIG. 2) remaining on the plurality of heads HE. In an embodiment, for example, the wiper WI may wipe the residual ink from the nozzle surfaces NS and/or the coating films (e.g., the first coating film COA, the second coating film COB, or the like.) of the plurality of heads HE.

In an embodiment, for example, the wiper WI may include a polyresin (e.g., polyester or the like), a fluorine resin (e.g., ETFE (ethylene tetrafluoro ethylene), or the like.). However, the disclosure is not limited thereto. In an embodiment, for example, the wiper WI may be used without restriction as long as the wiper WI can absorb the residual ink on the nozzle surfaces NS.

In an embodiment, for example, a second direction DR2 may cross the first direction DR1. In an embodiment, for example, the first direction DR1 and the second direction DR2 may be perpendicular to each other. In an embodiment, for example, the nozzle surfaces NS of the plurality of heads HE may be parallel to a plane defined by the first direction DR1 and the second direction DR2.

In an embodiment, for example, a third direction DR3 may cross the first direction DR1 and the second direction DR2. In an embodiment, for example, the first direction DR1, the second direction DR2, and the third direction DR3 may be perpendicular to each other. In an embodiment, for example, the nozzle surfaces NS of the plurality of heads HE may face the wiper WI in the third direction DR3.

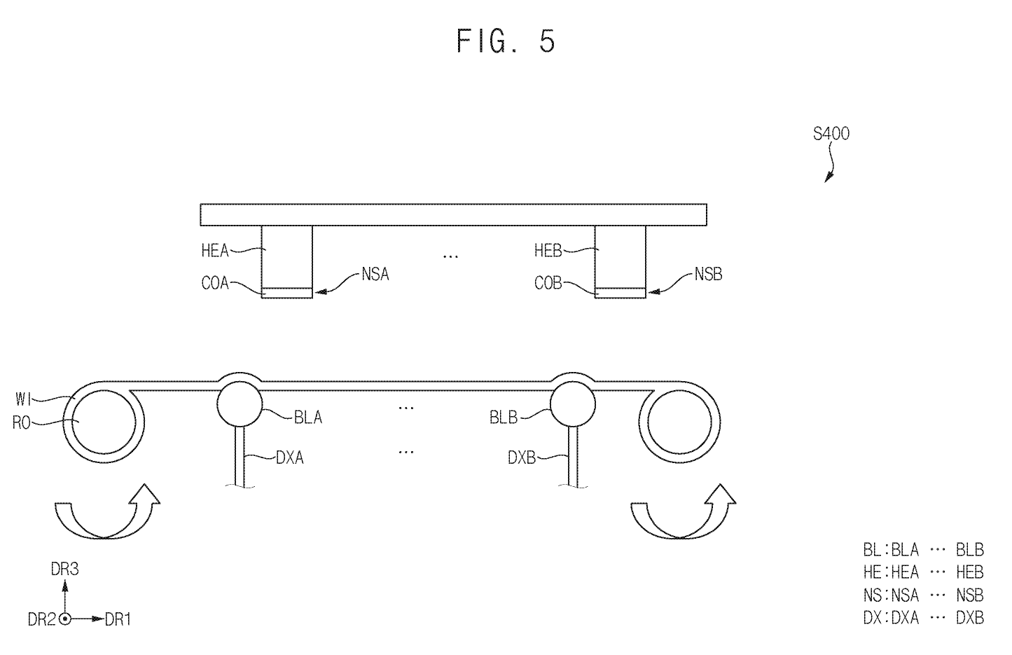

In an embodiment, for example, the plurality of heads HE may be a part of a device that performs the inkjet process of ejecting ink (e.g., IK of FIG. 5). In an embodiment, for example, the head pack may include five heads HE. In such an embodiment, the plurality of the blotters may also include five blotters BL. In such an embodiment, the plurality of heads HE and the plurality of blotters BL may correspond in a one-to-one ratio. In such an embodiment, one blotter BL may be used to perform blotting on one head HE. In an embodiment, for example, the plurality of heads HE may include a first head HEA and a second head HEB spaced apart in the first direction DR1. The first head HEA may correspond to the first blotter BLA. The second head HEB may correspond to the second blotter BLB.

The coating films may be formed on the plurality of heads HE. In an embodiment, for example, the first coating film COA may be positioned on a first nozzle surface NSA of the first head HEA. The second coating film COB may be positioned on a second nozzle surface NSB of the second head HEB.

In an embodiment, for example, the coating films may be formed on the nozzle surfaces NS to minimize an amount of ink remaining on the nozzle surfaces NS. In addition, the coating films may prevent the plurality of heads HE from wearing or being damaged. In an embodiment, for example, the coating films may be placed over the entire area of the nozzle surfaces NS. In an embodiment, for example, the residual ink may remain on the first coating film COA and the second coating film COB.

In an embodiment, for example, the coating film (e.g., each of the first coating film COA and the second coating film COB) may include a plurality of layers. In an embodiment, for example, the coating film may include a first first coating film (hereinafter, will be referred to as “1-1 coating film”), a second first coating film (hereinafter, will be referred to as “1-2 coating film”), and a third first coating film (hereinafter, will be referred to as “1-3 coating film”) positioned sequentially on the nozzle surfaces NS. In an embodiment, for example, the 1-1 coating film may be a coating film formed on the surface of the nozzle surfaces NS. The 1-2 coating film may be formed on the 1-1 coating film. The 1-3 coating film may be disposed or formed on the 1-2 coating film. The residual ink may be the ink remaining on the surface of the 1-3 coating film.

In an embodiment, for example, the 1-1 coating film, the 1-2 coating film, and the 1-3 coating film may include or be composed of different materials from each other.

In an embodiment, for example, the 1-1 coating film may include an organic layer.

In an embodiment, for example, the 1-2 coating film may include wear-resistant materials. In an embodiment, for example, the 1-2 coating film may include materials such as silicon oxycarbide (SiOC), silicon nitride (SiN), silicon boron nitride (SiBN), silicon oxynitride (SiOCN), silicon dioxide (SiO₂), silicon oxy nitride (SiON), aluminum oxide (Al₂O₃), silicon carbide (SiC), titanium nitride (TiN), titanium aluminum nitride (TiAlN), aluminum chromium nitride (AlCrN), or the like. These may be used alone or in combination with each other.

In an embodiment, for example, the 1-3 coating film may include a liquid-repellent material. In an embodiment, for example, the 1-3 coating film may include fluorine-based materials, silicone-based materials, or the like. These may be used alone or in combination with each other. The fluorine-based materials may include fluororesins, fluorocarbon films, and/or fluoropolymers. These may be used alone or in combination with each other. The silicone-based materials may include silicon resins.

However, the disclosure is not limited thereto. In an embodiment, for example, the coating films may include various materials in addition to the organic materials included in the organic layer, the wear-resistant material, and the liquid-repellent material. In another embodiment, for example, the coating films may include a single layer, two, four or more layers, each layer therein composed of different materials from each other.

FIGS. 2, 3, 4, 5, and 6, are views illustrating an embodiment of a maintenance method for the inkjet heads using the maintenance system for the inkjet heads of FIG. 1.

Referring to FIGS. 1 and 2, after the inkjet process, the maintenance system for the inkjet heads (e.g., the blotter BL and the wiper WI) may be elevated (e.g., moved in the third direction DR3) (S100).

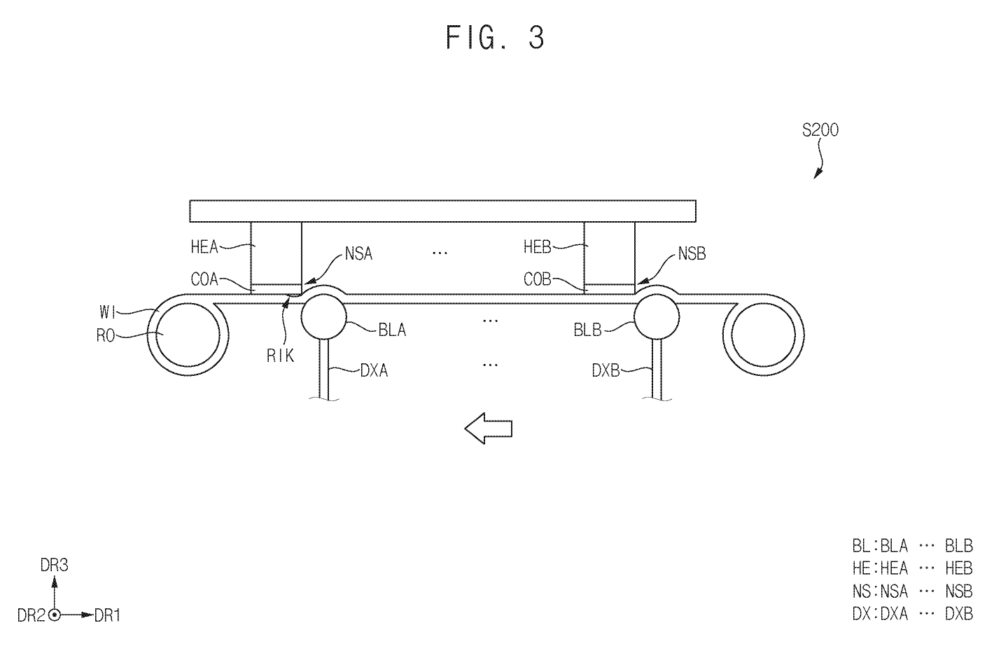

Referring to FIG. 3, pressing of the blotter BL may allow the wiper WI to come into contact with the nozzle surfaces (e.g., the coating films). The wiper may move in a predetermined distance in one direction (e.g., in an opposite direction to the first direction DR1) to wipe off the residual ink RIK (S200).

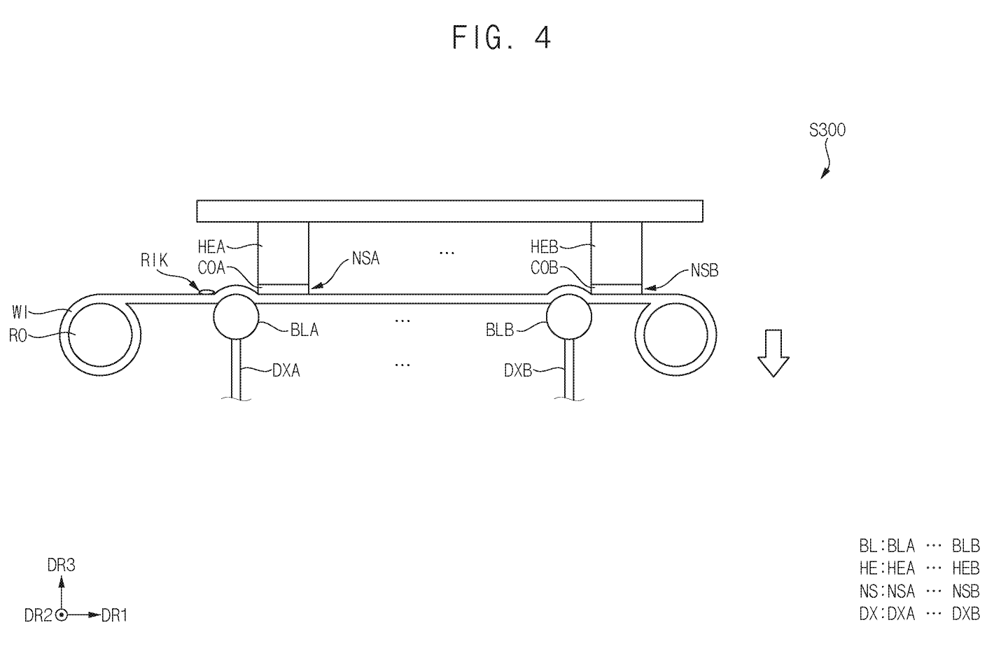

Referring to FIG. 4, after the blotting process, the maintenance system for the inkjet heads (e.g., the blotter BL and the wiper WI) may be lowered (e.g., move in an opposite direction to the third direction DR3) (S300).

Referring to FIG. 5, the used wiper WI may be wound onto a roller RO, and a new wiper WI may be supplied for the next blotting process (S400).

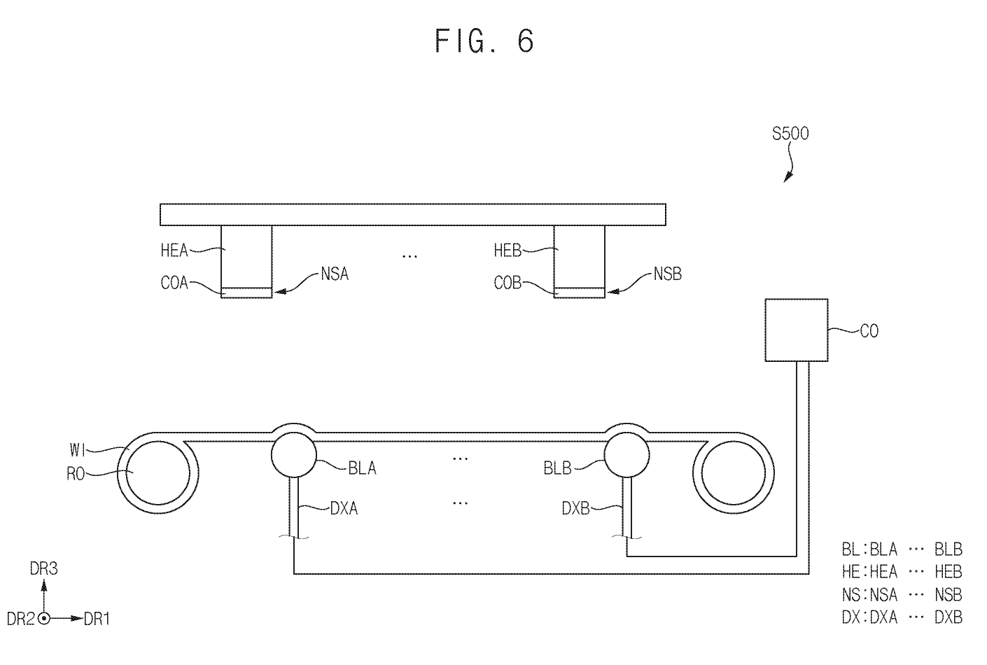

Referring to FIG. 6, after performing the blotting process a predetermined number of times, the positions of the plurality of blotters BL may be adjusted (S500).

The coating films may wear out as the blotting process is repeated. As the blotting process is repeated, the damage to the coating films may accumulate. In an embodiment, for example, when the blotting process is performed more than about 900 times, discharge defects may occur. The damage may cause surface irregularities in the coating films, or portions where liquid-repellency is lost due to delamination of the coating films.

In an embodiment, the plurality of drive axes DX may be connected to each of the plurality of blotters BL. In an embodiment, for example, the plurality of drive axes DX may include a first drive axis DXA and a second drive axis DXB which are spaced apart in the first direction DR1. In an embodiment, for example, the first drive axis DXA may be connected to the first blotter BLA, and the second drive axis DXB may be connected to the second blotter BLB.

In an embodiment, the controller CO may control the plurality of drive axes DX individually (or independently of each other). In an embodiment, for example, the positions of the plurality of blotters BL may be independently or independently adjusted depending on the movement of the plurality of drive axes DX. In an embodiment, the plurality of blotters BL may have a predetermined offset from the position prior to the position compensation.

In an embodiment, the controller CO may periodically perform individual position compensation of the plurality of blotters BL based on the wear deviations of the coating films. In an embodiment, the position compensation of a plurality of blotters BL may be carried out in a direction that reduces the wear deviations of the coating films. In an embodiment, the direction of reducing the wear deviations may be in the direction in which the gap between the plurality of blotters BL and the plurality of inkjet heads HE increases.

In an embodiment, in order to carry out the blotting process, each of a plurality of drive axes DX may drive the corresponding blotters BL upward (e.g., in the third direction DR3). The plurality of blotters BL may press the wiper WI against the nozzle surface NS.

In an embodiment, after the blotting process is performed, each of a plurality of drive axes DX may drive the corresponding blotters BL downward (e.g., in the opposite direction to the third direction DR3).

In an embodiment, after the blotting process for a predetermined number of cycles is performed, the position compensation of the plurality of blotters BL may be performed. In an embodiment, the controller CO may control the plurality of drive axes DX individually (or independently of each other). Each of the plurality of drive axes DX may drive each of the plurality of blotters BL.

Hereinafter, data forming a basis for the position compensation of the maintenance system for the inkjet heads according to the embodiments will be mainly described.

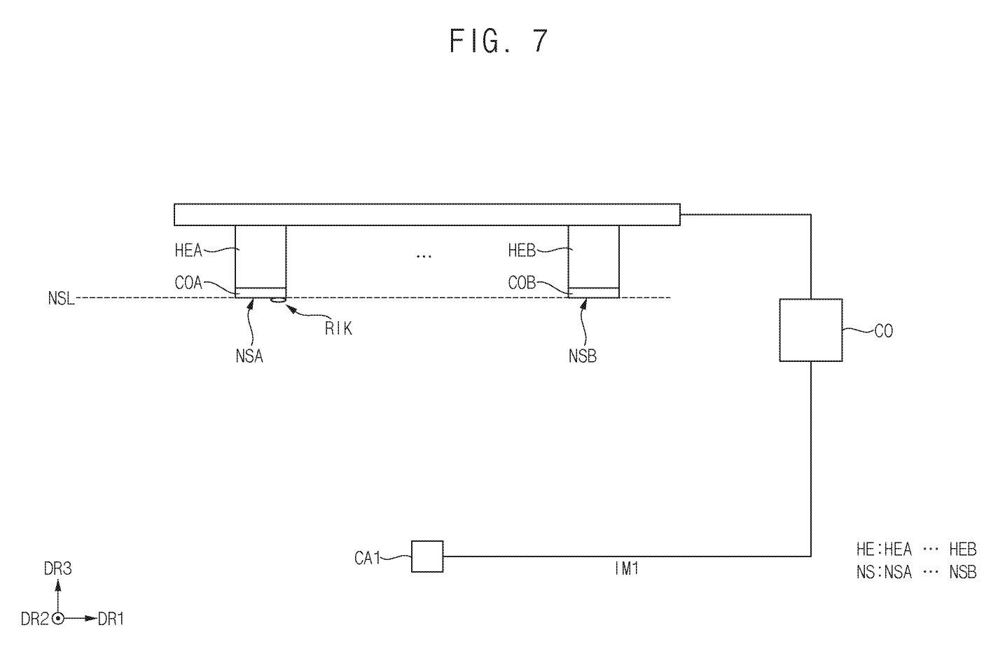

FIG. 7 is a view illustrating a first sensor included in the maintenance system for the inkjet heads of FIG. 1.

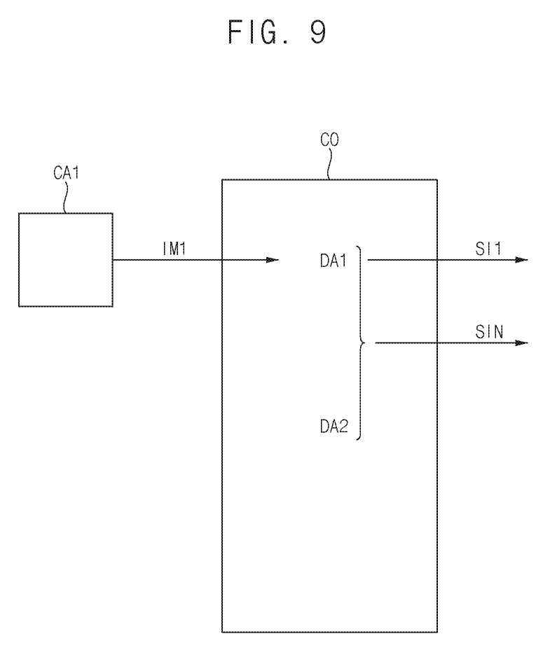

Referring to FIGS. 1 and 7, in an embodiment, a first sensor CA1 may be positioned below the nozzle surfaces NS. Accordingly, the first sensor CA1 may obtain a first image (e.g., a first image IM1 of FIG. 9) by photographing the coating films on the nozzle surfaces NS.

In an embodiment, for example, the nozzle surfaces NS may be positioned at the predetermined level NSL defined by the first direction DR1 and the second direction DR2. The predetermined level NSL may refer to a Z-axis coordinate of the plane defined by the first direction DR1 and the second direction DR2. However, since the nozzle surfaces NS are aligned with respect to the substrate on which the ink is ejected, the nozzle surfaces NS may not be positioned at a same level NSL.

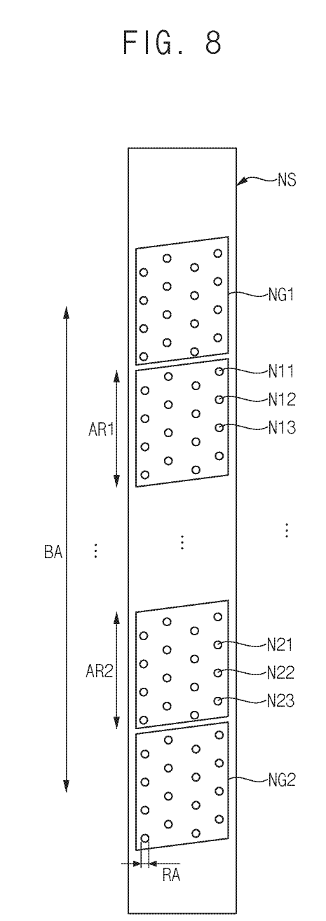

FIG. 8 is a view illustrating the first image acquired by the first sensor of FIG. 7.

Specifically, FIG. 8 is an image of one of the nozzle surfaces NS taken using the first sensor of FIG. 7.

In an embodiment, for example, a plurality of nozzle holes may be defined or formed in the nozzle surfaces NS. The ink may be ejected through the plurality of nozzle holes. In an embodiment, for example, the plurality of nozzle holes may have a predetermined diameter RA.

In an embodiment, for example, upper and lower portions of one head HE may include dummy nozzles (e.g., a first dummy nozzle NG1 and a second dummy nozzle NG2).

In an embodiment, for example, effective nozzles may be positioned between the dummy nozzles. The effective nozzles may mean nozzles used in the inkjet process. In an embodiment, for example, No. 11, 12, 13, 21, 22, and 23 nozzles N11, N12, N13, N21, N22, and N23 may be positioned sequentially in one direction.

In an embodiment, for example, the blotting process may be carried out within a blotting area BA including the dummy nozzles. As the blotting process is repeated, the degree of wear of a first portion AR1 and a second portion AR2 may be the same as or different from each other.

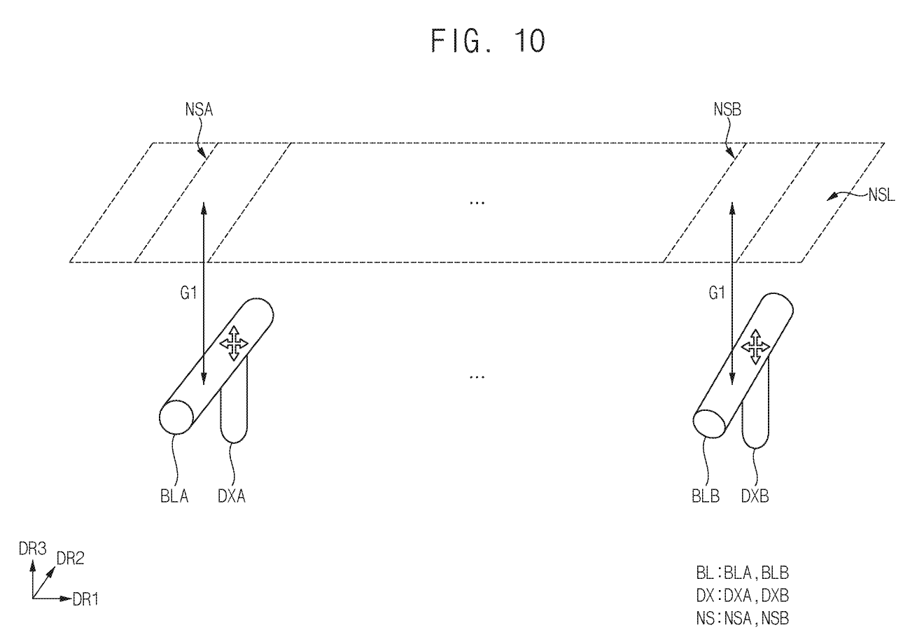

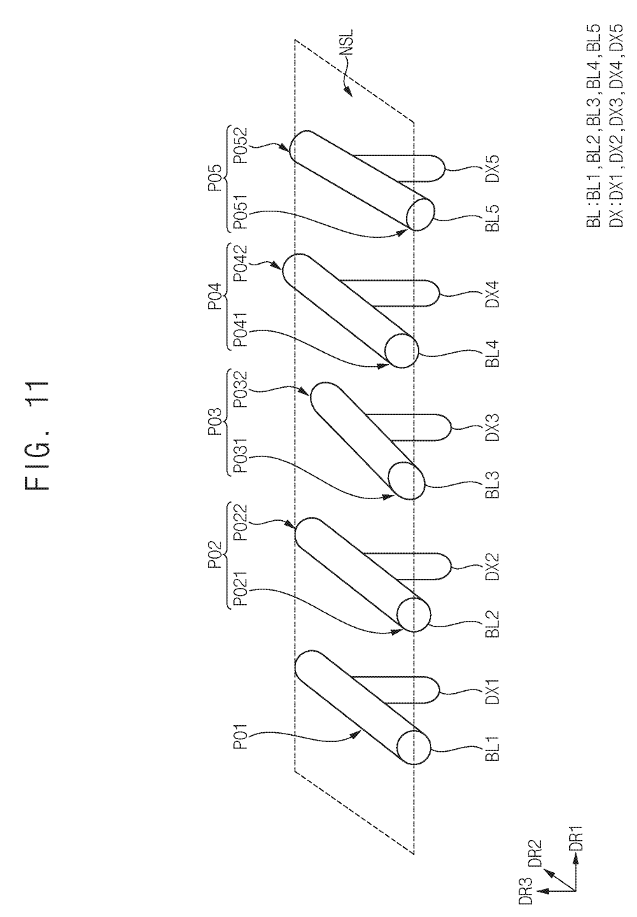

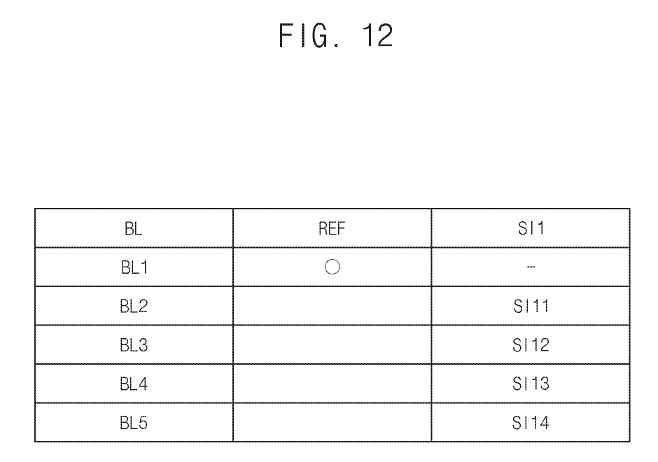

FIG. 9 is a view illustrating an embodiment of an operation of the controller included in the maintenance system for the inkjet heads of FIG. 1. FIGS. 10 and 11 are views illustrating an embodiment of the position compensation of the plurality of blotters by the controller of FIG. 9. FIG. 12 is a view illustrating an embodiment of a signal that forms a basis for the operation of the controller of FIG. 9.

Referring to FIG. 9, in an embodiment, the controller CO may receive the first image IM1 acquired by the first sensor CA1 and generate first data DA1 and second data DA2. In an embodiment, for example, the first data DA1 may be data corresponding to the blotter BL that causes the least damage. In an embodiment, for example, the second data DA2 may be stored in the controller CO. In an embodiment, for example, The data used to perform the blotting process may correspond to the second data DA2. In an embodiment, for example, the controller CO may generate first to N-th signals SI1-SIN based on the first data DA1. Here, N is a natural number greater than 1.

Referring to FIGS. 1 and 10, in an embodiment, the first coating film of the first head among the plurality of inkjet heads HE may exhibit the least amount of wear. The first blotter among the plurality of blotters BL may press the wiper WI against the first nozzle surface of the first head. The position compensation of the plurality of blotters BL may be performed based on the position of the first blotter.

In an embodiment, for example, the gap between the plurality of blotters BL and the plurality of nozzle surfaces NS may be non-uniform. In an embodiment, for example, the first blotter BLA may be spaced apart from the first nozzle surface NSA by a first gap G1. In an embodiment, for example, the second blotter BLB may be spaced apart from the second nozzle surface NSB by the second gap G2. In an embodiment, for example, the first gap G1 and the second gap G2 may be the same as or different from each other.

In an embodiment, for example, when the first gap G1 is greater than the second gap G2, the wear of the first coating film of the first nozzle surface NSA by the first blotter BLA may be greater than the wear of the second coating film of the second nozzle surface NSB by the second blotter BLB. In an embodiment, for example, among the plurality of heads HE, a head whose wear exceeds a certain threshold may be taken out of service. If the number of heads that have been discontinued exceeds a certain threshold, the entire of the head pack (i.e., all of the plurality of heads HE) may be discarded. In an embodiment, for example, if about 20% or more of the heads HE (e.g., about two) or more of the five heads HE that make up the pack are discontinued (due to increased tack time), the remaining three heads HE will be discarded even if still usable. As a result, the head pack may be discarded after only about 1/5 to about 1/8 of the period guaranteed by a head manufacturer.

In a case of the maintenance system for the inkjet heads according to a comparative example, the plurality of blotters BL may be driven collectively. In this case, as the blotting process is repeated, the wear variation caused by the gap deviation between the plurality of blotters BL and a plurality of nozzle surfaces NS may be increased. Accordingly, the head pack may need to be replaced more frequently.

In the maintenance system for the inkjet heads according to embodiments of the disclosure, the plurality of blotters BL may be individually controlled or controlled independently of each other. In an embodiment, for example, there may be the wear deviations among the coating films. The disclosure may compensate for the positions of the plurality of blotters BL in a direction that reduces the wear deviations (i.e., in the direction that reduces variation and makes the wear of the plurality of blotters BL more uniform). By minimizing the wear deviations, the replacement cycle of the head pack may be extended. Accordingly, cost of maintenance and/or replacement of the head pack may be reduced.

In an embodiment, for example, when the degree of wear of the first coating film of the first nozzle surface NSA is greater than the degree of wear of the second coating film of the second nozzle surface NSB, the degree of wear of the first coating film by the first blotter BLA may be adjusted to match that of the second coating film by the second blotter BLB.

Referring to FIGS. 1 and 11, in an embodiment, the degree of wear of the first coating film of the first head may be the smallest among the coating films of the plurality of inkjet heads HE. The first coating film of the first head may include a 1-1 portion with a relatively smaller degree of wear and a 1-2 portion with a relatively greater degree of wear than the 1-1 portion. The first blotter of the plurality of blotters BL may press the first nozzle surface of the first head against the wiper WI. A first portion of the first blotter may press the wiper WI against the 1-1 portion of the coating film. A second portion of the first blotter may press the wiper WI against the 1-2 portion of the coating film. The position compensation of the blotters BL may be performed based on the position of the first portion of the first blotter.

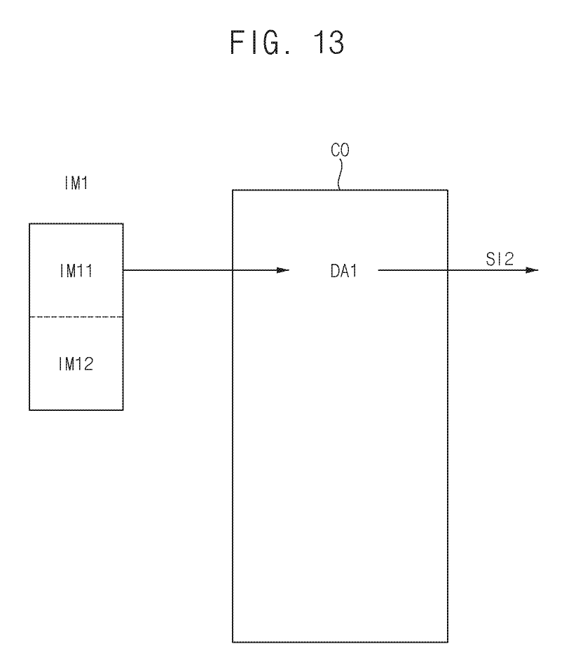

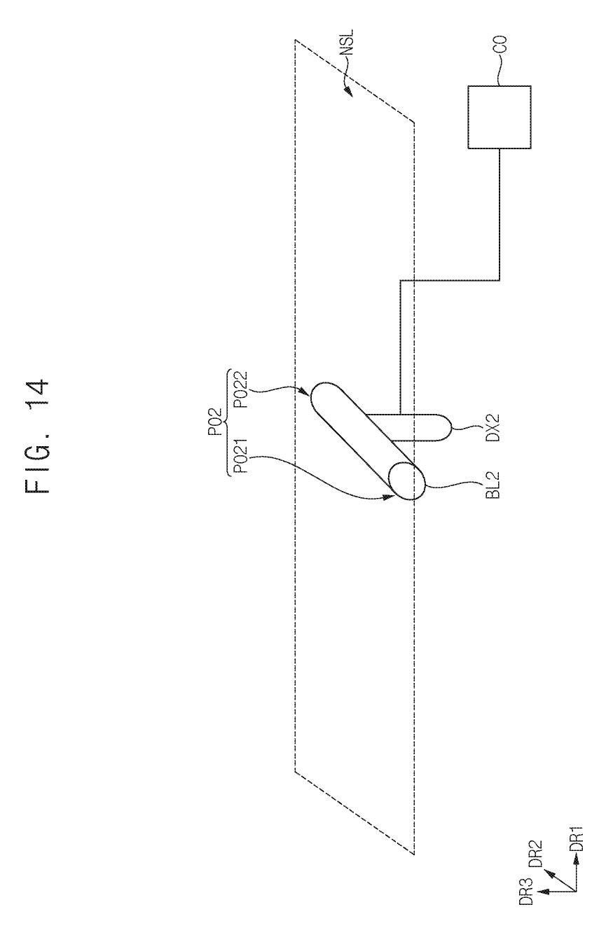

The maintenance system for the inkjet heads according to the embodiments of the disclosure may be driven not only in the third direction DR3 and its opposite direction to the third direction DR3 thereto (e.g., linearly) but also in a rotational direction (e.g., rotational motion in the theta (θ) direction driving on the plane defined by the first direction DR1 and the second direction DR2). Detailed features of the theta direction driving will be described below with reference to FIGS. 13 and 14.

For example, in the case of the maintenance system for the inkjet head according to the comparative example, the head pack was replaced every about 1 month to about 1.5 months, while the maintenance system for the inkjet heads according to embodiments of the disclosure may replace the head pack for the entire period (e.g., about 8 months) warranted by the head manufacturer. Accordingly, the cost of maintenance and/or replacement of the head pack may be further reduced.

In an embodiment, for example, referring to FIGS. 9, 10, 11, and 12, a blotter that caused the least damage to the inkjet head HE may be detected among first to fifth blotters (BL1, BL2, BL3, BL4, BL5). In an embodiment, for example, the first blotter BL1 may be the blotter that serves as a reference REF for the position compensation.

Based on the position of the reference REF blotter, the position compensation instructions for the remaining blotters may be generated. In an embodiment, for example, a first signal SI1 may be a signal provided to the second drive axis DXB for position compensation of the second blotter BL2. An N-th signal SIN may be a signal provided to the (N+1)-th drive axis to compensate the position of the (N+1)-th blotter (e.g., the N may be a natural number greater than or equal to 3). However, this is merely an example, and the position compensation of the plurality of blotters BL may be performed in various ways.

In an embodiment, the controller CO may match the first data DA1 with the second data DA2. In an embodiment, the second data DA2 may include a speed of the plurality of blotters BL, the height of the plurality of blotters BL, the degree of tilt of the plurality of blotters BL, or the like. In an embodiment, for example, the second data DA2 may be data stored within the controller CO or stored in a separate memory. In addition, the second data DA2 may be an input value and/or adjustable parameter.

In an embodiment, the controller CO may match the first data DA1 and the second data DA2 to predict the position compensation cycle of the plurality of blotters BL and/or the replacement cycle of the head pack. The controller CO may generate the signal SIN including the position compensation cycle, the replacement cycle, or the like. The signal SIN may include a plan for position compensation or the replacement, and may trigger an alarm at predetermined intervals. In an embodiment, for example, the signal SIN may be combined with sensing data of various sensors to predict the plan, such as the position compensation, the replacement, or the like, more precisely. In an embodiment, for example, the signal SIN may use machine learning, data analysis technology, or the like, to predict the plan, such as the position compensation, the replacement, or the like, more precisely. The alarm may also be expressed in a form of a warning sound, a message displayed on the display, or the like. However, the disclosure is not limited thereto. In embodiments, the information included in the signal SIN and the form of the alarm may be changed in various ways.

The maintenance system for the inkjet heads according to embodiments of the disclosure may perform the blotting process for a predetermined period, and then perform the position compensation.

The position compensation may be carried out in a manner that minimizes the wear deviations of the coating films while enabling the blotting process. In an embodiment, for example, if the gap between the plurality of blotters BL and the nozzle surfaces NS is too small, the coating films on the nozzle surfaces NS may be severely damaged due to friction of the plurality of blotters BL. In such an embodiment, if the gap between the plurality of blotters BL and the nozzle surfaces NS is too large, the plurality of blotters BL may not be able to clean the residual ink on the nozzle surfaces NS. Accordingly, the position compensation may be a correction in which the position of the plurality of blotters BL is in a position that minimizes the wear deviations of the coating films while still allowing effective blotting process.

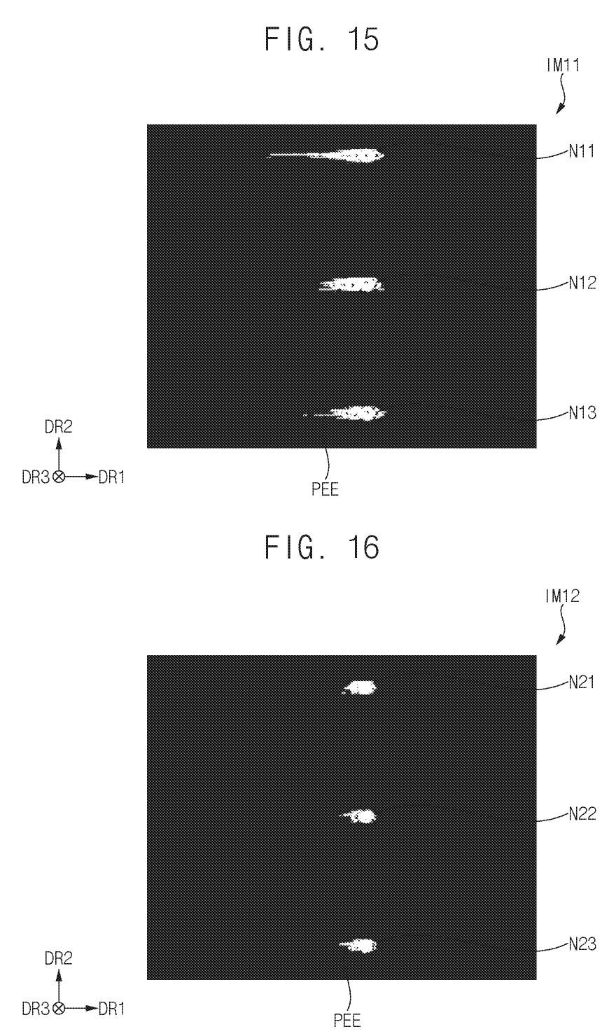

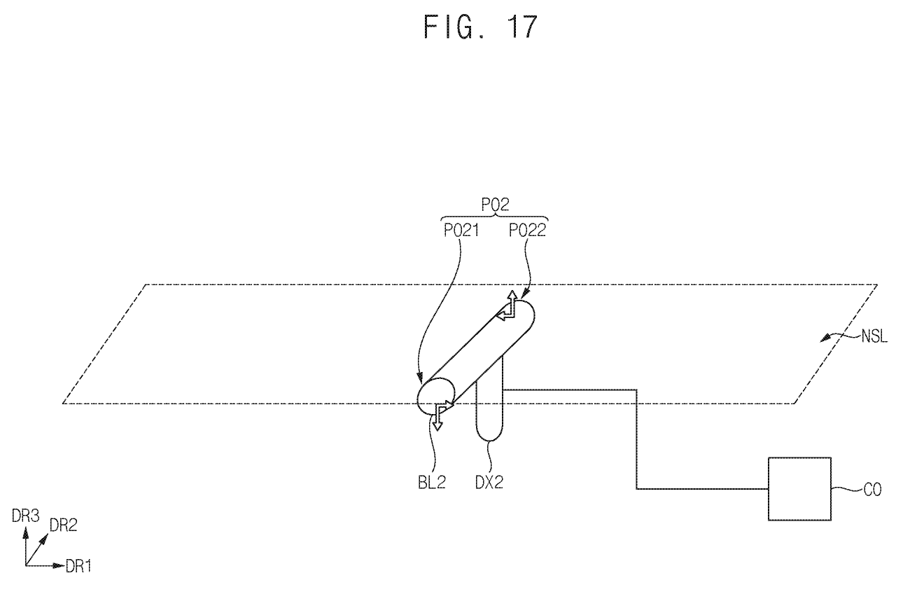

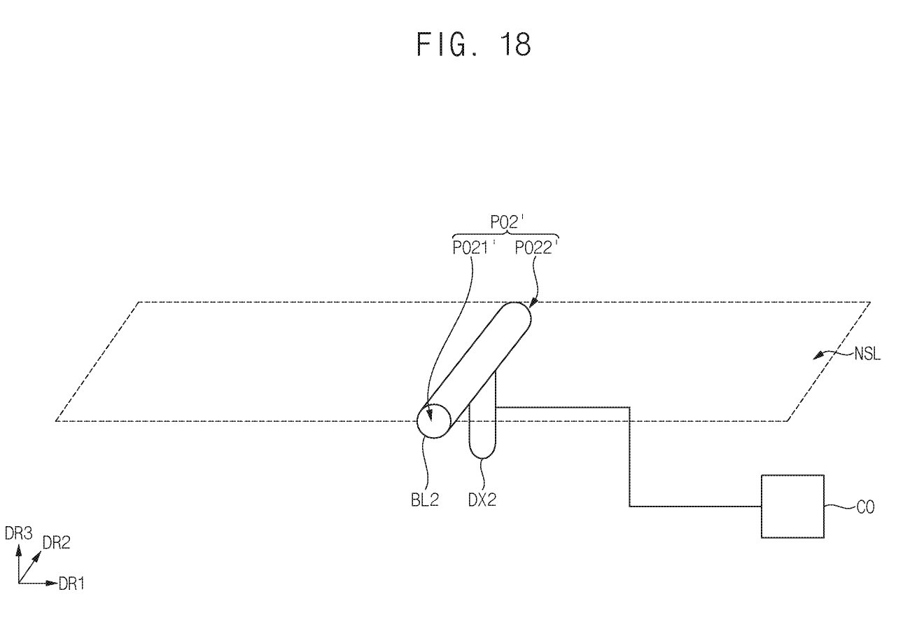

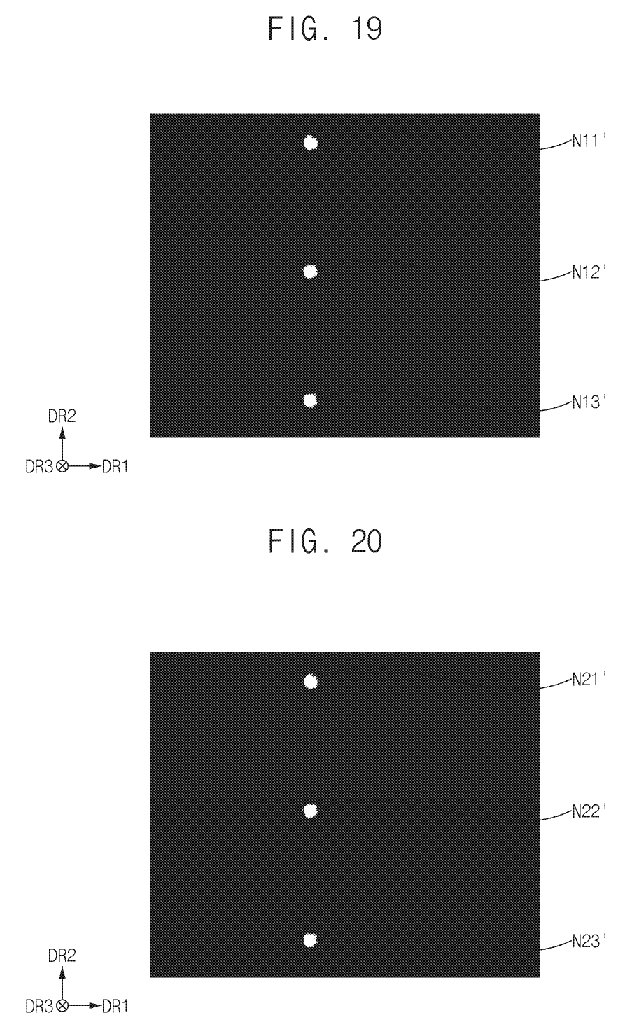

FIGS. 13 and 14 are views illustrating embodiments of the operation of the controller included in the maintenance system for the inkjet heads of FIG. 1. FIGS. 15 and 16 are images that serve as a basis for the operation of the controller of FIG. 1. FIG. 17 is a view illustrating the position compensation of the blotter based on the images of FIGS. 15 and 16. FIG. 18 shows the blotter after performing the position compensation of FIG. 17. FIGS. 19 and 20 are images illustrating effects of the maintenance system for the inkjet head of FIG. 1.

Referring to FIGS. 1, 7, 11, 13, and 14, in an embodiment, a first sensor SE1 may acquire images of split regions of the nozzle surfaces NS (e.g., a first split image IM11 and a second split image IM12). The controller CO may instruct position compensation of the plurality of blotters BL based on the images of the split regions. In an embodiment, for example, a second signal SI2 may control the drive axis (e.g., the second drive axis DX2) so that the positions of the portions corresponding to a first position (e.g., PO21) and a second position (e.g., PO22) on a single blotter (e.g., the second blotter BL2) may be individually adjusted or adjusted independently of each other.

In an embodiment, for example, the wear deviations may occur depending on the position of the nozzle surface NS of one head HE.

In an embodiment, for example, based on the predetermined level NSL, the second to fifth blotters BL2, BL3, BL4, BL5 except for the first blotter BL1 may be desired to be compensated for position. In an embodiment, for example, a first position PO1 of the first blotter BL1 may be positioned at the predetermined level NSL. A first position PO21 of the second blotter BL2 may be positioned at the predetermined level NSL, while a second position PO22 may be positioned below the predetermined level NSL (i.e., in the opposite direction to the third direction DR3). A first position PO31 of the third blotter BL3 may be positioned above the predetermined level NSL (i.e., in the third direction DR3), and a second position PO32 may be positioned below the predetermined level NSL. A first position PO41 of the fourth blotter BL4 may be positioned above the predetermined level NSL, and a second position PO42 may be positioned below. A first position PO51 and a second position PO52 of the fifth blotter BL5 may be positioned below the predetermined level NSL. If positioned below the predetermined level NSL, the nozzle surfaces NS may not be able to be cleaned, and if positioned above the predetermined level NSL, it may cause great damage to the coating films of the nozzle surfaces NS (the wear). Therefore, in this case, the positions of the other blotters except for the first blotter BL1 and the first position PO21 of the second blotter BL2 may be desired to be compensated.

In a case, for example, the first portion corresponding to the first position PO31 in the third blotter BL3 may have a greater degree of wear than the second portion corresponding to the second position PO32 in the third blotter BL3. In such a case, the maintenance system for the inkjet heads according to embodiments of the disclosure may compensate for the positions of the plurality of blotters BL in a manner that reduces the wear deviation between the first portion and the second portion. In an embodiment, for example, the position of the blotters may be corrected based on the portion with the smallest wear (e.g., the portion corresponding to the first position PO21 of the second blotter BL2) in the blotter BL corresponding to the first position PO21 of the second blotter BL2) in the blotter BL corresponding to the inkjet heads HE with the smallest degree of wear.

Referring to FIGS. 15 and 16, in the first split image IM11, the damage is greater in the order of a first nozzle N11, a second nozzle N12, and a third nozzle N13. Referring to the second split image IM12, nozzles N21, N22, N23 that have less damage than the nozzles contained in the first split image IM11 are shown. In this case, it can be understood that the position compensation of the blotter is desired to minimize the damage to the portion corresponding to the first split image IM11.

Referring to FIG. 17, the controller CO may instruct the second drive axis DX2 to move the first position PO21 corresponding to the first split image IM11 downward and to the right, and the second position PO22 corresponding to the second split image IM12 upward and to the left. Referring to FIG. 18, according to the position compensation, a position PO2’ of a compensated second blotter BL2’ (e.g., both a first position PO21’ and a second position PO22’) may be positioned at the predetermined level NSL. Accordingly, the inkjet heads HE corresponding to the second blotter BL2 may be cleaned and at the same time the damage caused by the blotting process may be reduced.

Referring to FIGS. 19 and 20, it can be confirmed that the peeling damage has been reduced according to the position compensation unlike in FIGS. 15 and 16.

The gaps between the plurality of inkjet heads HE and the plurality of blotters BL may vary. The deviation in the gaps may result in variation in damage inflicted on the plurality of inkjet heads HE by the friction from the plurality of blotters BL (e.g., peeling of the coating films on the nozzle surfaces NS of the plurality of inkjet heads HE). Embodiments of the disclosure may compensate for the position of the blotters BL based on the blotter BL corresponding to the inkjet head HE that has received the least amount of damage. Accordingly, the damage inflicted on the inkjet head HE may be reduced. Accordingly, the wear deviations of the plurality of inkjet heads HE may be reduced, and the lifetime of the head pack including the plurality of inkjet heads HE may be improved.

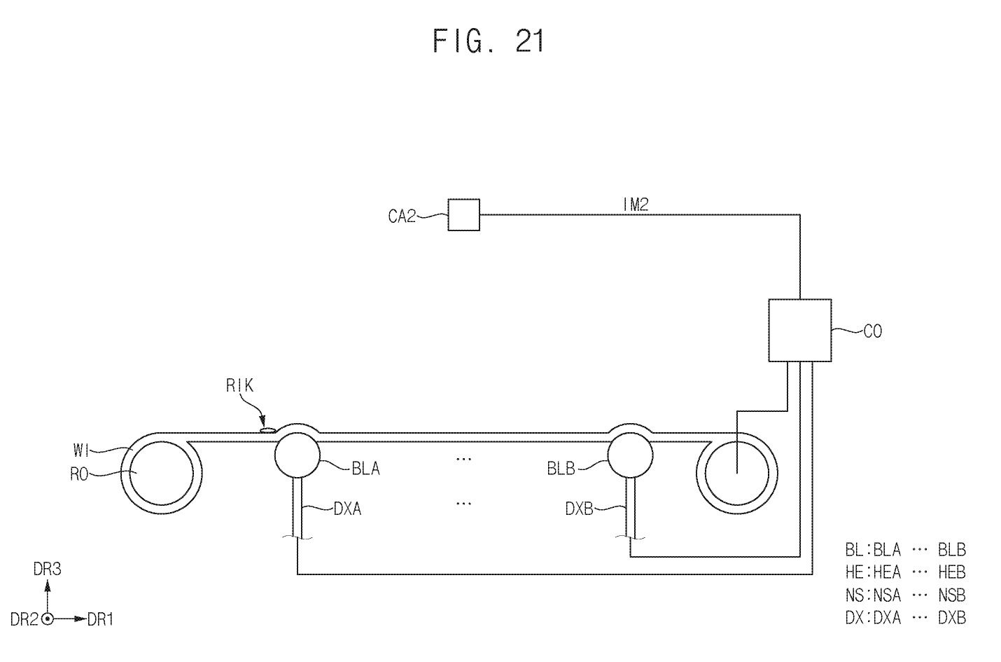

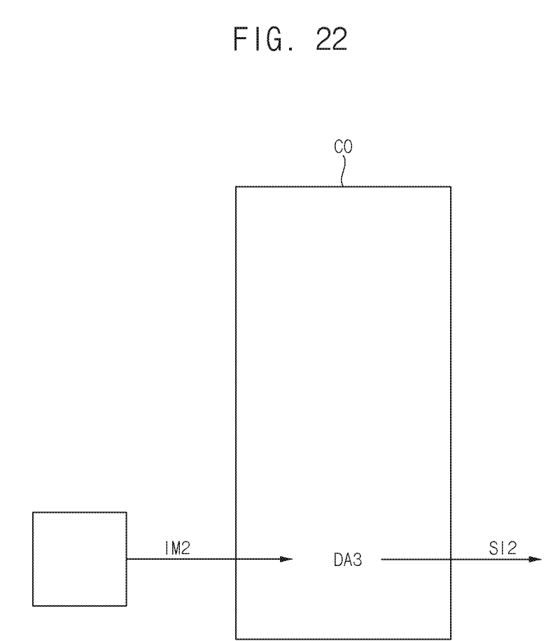

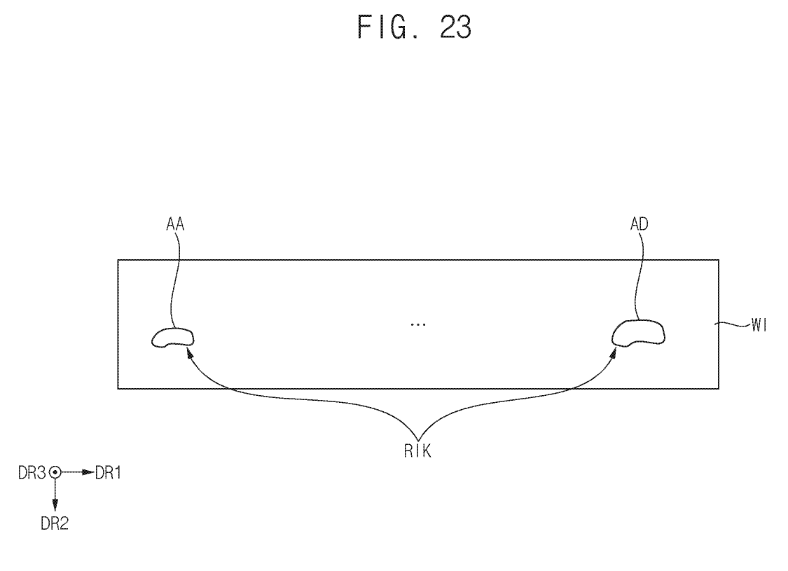

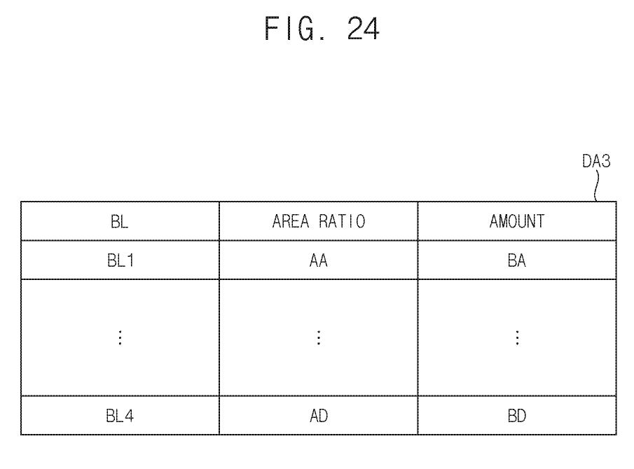

FIG. 21 is a view illustrating a second sensor included in the maintenance system for the inkjet heads of FIG. 1. FIG. 22 is a view illustrating an embodiment of the operation of the controller included in the maintenance system for the inkjet heads of FIG. 1. FIG. 23 is a view illustrating an image acquired by the second sensor of FIG. 21. FIG. 24 is a view illustrating an embodiment of the position compensation of the plurality of blotters based on the image of FIG. 23.

Hereinafter, any repetitive detailed descriptions of the same or like elements as those of embodiments of the maintenance system for the inkjet heads described above with reference as described with reference to FIGS. 1 to 20 will be omitted or simplified.

Referring to FIGS. 1, 21, 22, 23, and 24, in an embodiment, the maintenance system for the inkjet heads may include a second sensor CA2 configured to photograph (or to acquire an image of) the wiper WI. The controller CO may periodically perform the position compensation of the plurality of blotters BL based on the deviation in the amount of ink absorbed by the wiper WI.

In an embodiment, for example, the second sensor CA2 may acquire a second image. The controller CO may calculate an area ratio of the portions where the residual ink RIK has been absorbed in the second image. Based on the area ratio, a third data DA3 including a deviation of the amount of ink absorbed by the wiper WI may be calculated.

In an embodiment, for example, referring to the third data DA3, the first blotter BL1 may have a first area ratio AA, based on which a first ink volume BA may be determined to have been absorbed by the wiper WI. The fourth blotter BL4 may have a second area ratio A2, based on which a second ink volume BD may be determined to have been absorbed by the wiper WI.

In an embodiment, the amount of residual ink that is absorbed by the wiper WI from the first head among the plurality of inkjet heads HE may be the smallest.

In an embodiment, the first blotter among the plurality of blotters BL may press the wiper WI against the first nozzle surface of the first head. The position compensation of the plurality of blotters BL may be performed based on the position of the first blotter.

In an embodiment, the first head may include the 1-1 portion with the relatively smaller residual ink amount and the 1-2 portion with the relatively larger amount of ink than the 1-1 portion. The first portion of the first blotter may press the 1-1 portion of the first head against the wiper WI. The second portion of the first blotter may press the wiper WI against the 1-2 portion of the first head. The position compensation of the plurality of blotters BL may be performed based on the position of the first portion of the first blotter.

In an embodiment, the first head may include a 1-1 portion with a relatively smaller residual ink amount and a 1-2 portion with a relatively larger amount of ink than the 1-1 portion. The first portion of the first blotter may press the 1-1 portion against the first head with the wiper WI on the top. The second portion of the first blotter may press the wiper WI against the 1-2 portion of the first head. The position compensation of the plurality of blotters BL may be performed based on the position of the first portion of the first blotter.

In an embodiment, the position compensation of the plurality of blotters BL may be performed in the direction of reducing the amount of residual ink absorbed by the wiper WI. In an embodiment, the direction of reducing the amount of residual ink absorbed by the wiper WI may be in the direction in which the gap between the plurality of blotters BL and the plurality of inkjet heads HE increases.

In an embodiment, the controller CO may match the speed of the plurality of blotters BL, the height of the plurality of blotters BL, and the degree of tilt of the plurality of blotters BL with the amount of residual ink absorbed by the wiper WI, and may predict the position compensation cycle of the plurality of blotters BL and/or the replacement cycle of the head pack including the plurality of inkjet heads HE.

According to the gap deviations between plurality of inkjet heads HE and the plurality of blotters BL, the deviations in damage applied to the plurality of inkjet heads HE may occur. As the damage increases, the nozzle surfaces NS may lose their liquid-repellency and become more hydrophilic, resulting in an increase in the amount of the residual ink remaining in the plurality of inkjet heads HE (i.e., the amount of residual ink). Accordingly, the amount of the residual ink absorbed by the wiper WI may increase. The disclosure may compensate for the position of the blotters BL based on the portion where the least amount of residual ink is absorbed by the wiper WI. Accordingly, the damage inflicted on plurality of inkjet heads HE may be reduced. Accordingly, the wear deviation of the plurality of inkjet heads HE may be reduced, and the lifetime of the head pack including the plurality of inkjet heads HE may be improved.

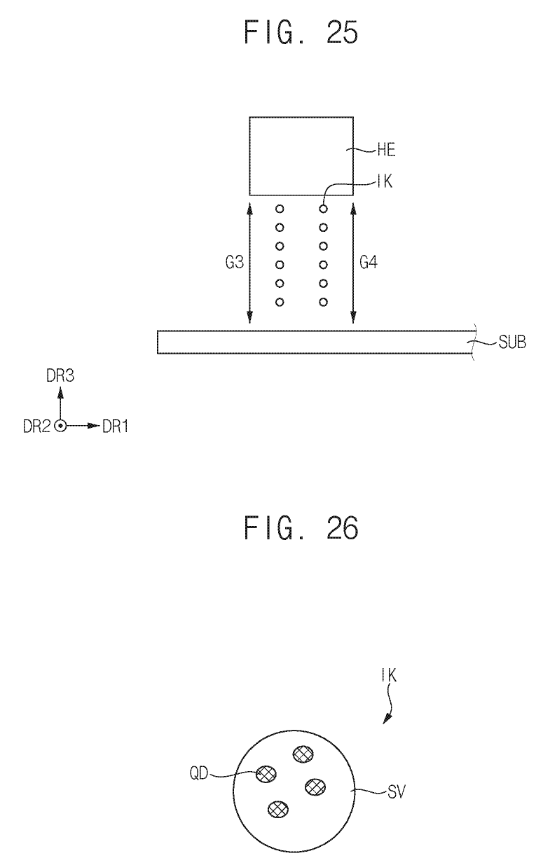

FIG. 25 is a view illustrating an inkjet head that is maintained by the maintenance system for the inkjet heads of the disclosure. FIG. 26 is a view illustrating ink ejected by the inkjet heads of FIG. 25.

Referring to FIGS. 25 and 26, in an embodiment, the residual ink (e.g., RIK of FIG. 2) may include quantum dot particles QD dispersed in a dispersant SV. One head pack HE may have gaps (e.g., G3, G4, or the like.) adjusted relative to the substrate SUB onto which the ink IK is ejected.

However, the maintenance system for the inkjet heads may not be flat because the wiper (WI of FIG. 1) has a cloth shape, and the gap deviation between the head pack and the maintenance system for the inkjet heads may occur due to machining deviations of the blotters (BL of FIG. 1), or the like.

According to the gap deviation, as the blotting process is repeated, scratches of the coating film (the damage) may be more induced by the quantum dot particles QD included in the residual ink.

The maintenance system for the inkjet heads according to embodiments of the disclosure may minimize the damage deviations caused by the gap deviations, thereby lengthening the replacement cycle of the head pack.

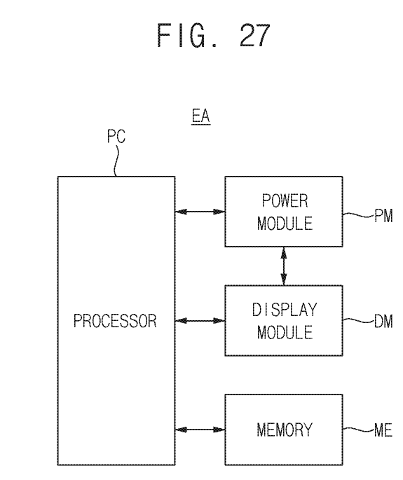

FIG. 27 is a block diagram of electronic devices according to an embodiment.

Referring to FIG. 27, an electronic device EA according to an embodiment may include a display module DM, a processor PC, a memory ME, and a power module PM.

The processor PC may include a central processing unit (“CPU”), an application processor (“AP”), a graphic processing unit (“GPU”), a communication processor (“CP”), an image signal processor (“ISP”), and/or a controller.

Data information used for operation of the processor PC or the display module DM may be stored in the memory ME. When the processor PC executes an application stored in the memory ME, an image data signal and/or an input control signal is transmitted to the display module DM, and the display module DM may process received signal and output image information through a display screen.

The power module PM may include a power supply module such as a power adapter and/or a battery device, and a power conversion module that converts power supplied by the power supply module to generate power used for operation of the electronic device EA.

At least one of the components of the electronic device EA described above may be included in the display device according to the above-described embodiments. In addition, some of the individual modules functionally included in one module may be included in the display device, and others may be provided separately from the display device. In an embodiment, for example, the display device may include the display module DM, and the processor PC, the memory ME, and the power module PM may be provided in the form of another device in the electronic device EA other than the display device. In an embodiment, the display device may operate based on the image data signal and the input control signal.

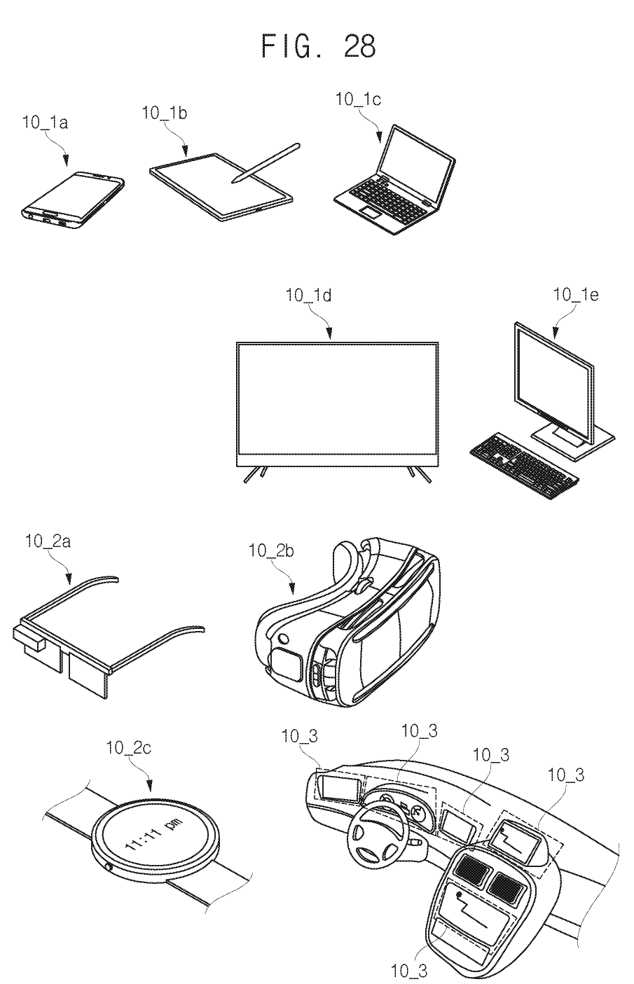

FIG. 28 is a schematic diagram of an electronic device according to various embodiments.

Referring to FIG. 28, one or more suitable electronic devices to which display devices according to an embodiment are applied may include not only electronic devices for image display such as a smartphone 10_1a, a tablet personal computer (“PC”) 10_1b, a laptop 10_1c, a television (“TV”) 10_1d, a desk monitor 10_1e, and/or the like, but wearable electronic devices including display modules such as a smart glass 10_2a, a head mounted display 10_2b, a smart watch 10_2c, and/or the like, vehicle electronic device 10_3 including display modules such as on a vehicle's instrument panel, a center fascia, a center information display (“CID”) located on a dashboard, a room mirror display, and/or the like.

An electronic apparatus according to an embodiment of the disclosure may include a display device configured to display an image and including a substrate and a pattern formed on the substrate by the plurality of inkjet heads, and a processor configured to transmit an image data signal and an input control signal to the display device, the inkjet heads may be maintained by a maintenance system for the inkjet heads. The maintenance system of the plurality of heads may include the wiper configured to absorb the residual ink remaining on the nozzle surfaces of the inkjet heads, the plurality of blotters configured to press the wiper against the nozzle surfaces, and the controller configured to periodically perform individual position compensation of the plurality of blotters in the direction that reduces the gap deviation between the plurality of inkjet heads and the plurality of blotters.

In an embodiment, the maintenance system for the inkjet heads may include the first sensor for photographing (or acquiring an image of) the coating films on the nozzle surfaces of the plurality of inkjet heads, and at least one additional sensor for photographing (or acquiring an image of) the wiper. The controller may adjust the gap between the plurality of inkjet heads and the plurality of blotters based on the image obtained from the first sensor or at least one of the second sensors.

The gaps between the plurality of inkjet heads and the plurality of blotters may vary. According to the deviation in the gaps, the damage inflicted on the plurality of heads by friction of the plurality of blotters (e.g., peeling of the coating film on the nozzle surfaces of the plurality of inkjet heads, or the like) may occur. The disclosure may compensate for the position of the blotters based on the blotter corresponding to the inkjet head that has suffered the least damage. Accordingly, the damage inflicted on the inkjet head may be reduced, the wear deviations of the plurality of inkjet heads may be reduced, and the lifetime of the head packs including the plurality of inkjet heads may be improved.

In addition, according to the gap deviation between the plurality inkjet heads and the plurality of blotters, the damage deviation inflicted on the plurality of inkjet heads may occur. As the damage increases, the nozzle surfaces may further lose their liquid-repellency and become more hydrophilic, resulting in the increase in the amount of the residual ink remaining in the plurality inkjet heads (i.e., the amount of residual ink). Accordingly, the amount of the residual ink absorbed by the wiper. The disclosure may compensate for the position of the blotters based on the portion where the least amount of the residual ink is absorbed by the wiper. Accordingly, the damage of the inkjet head may be reduced. Accordingly, the wear deviations of the plurality of inkjet heads may be reduced, and the lifetime of the head pack including the plurality of inkjet heads may be improved.

The maintenance system for the inkjet heads may be applied to a computer, a notebook, a mobile phone, a smartphone, a smart pad, a portable media player (“PMP”), a personal digital assistance (“PDA”), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A maintenance system for inkjet heads, comprising:
a first sensor which acquires an image of coating films on nozzle surfaces of the inkjet heads;
a wiper which absorbs residual ink remaining on the inkjet heads;
a plurality of blotters which presses the wiper against the nozzles surfaces; and
a controller which periodically performs position compensation of the plurality of blotters based on wear deviations of the coating films.

2. The maintenance system for the inkjet heads of claim 1, wherein,
the plurality of blotters has a predetermined offset from respective positions before the position compensation.

3. The maintenance system for the inkjet heads of claim 1, wherein,
a first coating film of a first head among the coating films of the inkjet heads has the least wear,
a first blotter among the plurality of blotters presses the wiper against a first nozzle surface of the first head, and
the position compensation of the blotters is performed based on a position of the first blotter.

4. The maintenance system for the inkjet heads of claim 1, wherein,
a first coating film of a first head among the coating films of the inkjet heads has the least wear,
the first coating film includes a first first portion having relatively lesser wear and a second first portion having relatively greater wear than the first first portion,
a first blotter among the plurality of blotters presses the first nozzle surface of the first head against the wiper,
a first portion of the first blotter presses the wiper against the first first portion of the first coating film, and a second portion of the first blotter presses the wiper against the second first portion of the first coating film, and
the position compensation of the plurality of blotters is performed based on a position of the first portion of the first blotter.

5. The maintenance system for the inkjet heads of claim 1, wherein the position compensation of the plurality of blotters is performed in a direction to reduce the wear deviations of the coating films.

6. The maintenance system for the inkjet heads of claim 5, wherein,
the direction to reduce the wear deviations corresponds to a direction in which a gap between the plurality of blotters and the inkjet heads increases.

7. The maintenance system for the inkjet heads of claim 1, wherein, the residual ink includes quantum dot particles.

8. The maintenance system for the inkjet heads of claim 1, wherein,
the controller matches speeds, heights, and tilt values of the plurality of blotters with the wear deviations to predict a cycle for the position compensation of the plurality of blotters.

9. The maintenance system for the inkjet heads of claim 1, wherein,
the controller matches speeds, heights, and tilt values of the plurality of blotters with the wear deviations to predict a replacement cycle of a head pack including the inkjet heads.

10. A maintenance system for inkjet heads, comprising:
a wiper which absorbs residual ink remaining on the inkjet heads;
a plurality of blotters which presses the wiper against nozzle surfaces of the inkjet heads;
a second sensor which acquires an image of the wiper; and
a controller which periodically performs position compensation of the plurality of blotters based on deviations in an amount of ink absorbed by the wiper.

11. The maintenance system for the inkjet heads of claim 10, wherein, the plurality of blotters has a predetermined offset from respective positions before the position compensation.

12. The maintenance system for the inkjet heads of claim 10, wherein,
a first head among the inkjet heads has the smallest amount of ink absorbed by the wiper,
a first blotter among the plurality of blotters presses the wiper against a first nozzle surface of the first head, and
the position compensation of the plurality of blotters is performed based on a position of the first blotter.

13. The maintenance system of the inkjet heads of claim 10, wherein,
a first head among the inkjet heads has the smallest amount of ink absorbed by the wiper,
the first head includes a first first portion having relatively lesser residual ink and a second first portion having relatively greater residual ink than the first first portion,
a first blotter among the plurality of blotters presses the first nozzle surfaces of the first head against the wiper,
a first portion of the first blotter presses the wiper against the first first portion of the first head, and a second portion of the first blotter presses the wiper against the second first portion of the first head, and
the position compensation of the plurality of blotters is performed based on a position of the first portion of the first blotter.

14. The maintenance system for the inkjet heads of claim 10, wherein,
the position compensation of the plurality of blotters is performed in a direction to reduce an amount of residual ink absorbed by the wiper.

15. The maintenance system for the inkjet heads of claim 14, wherein,
the direction to reduce an amount of residual ink absorbed by the wiper corresponds to a direction in which a gap between the plurality of blotters and the inkjet heads increases.

16. The maintenance system for the inkjet heads of claim 10, wherein, the residual ink includes quantum dot particles.

17. The maintenance system for the inkjet heads of claim 10, wherein,
the controller matches speeds, heights, and tilt values of the plurality of blotters with an amount of residual ink absorbed by the wiper to predict a cycle for the position compensation of the plurality of blotters.

18. The maintenance system for the inkjet heads of claim 10, wherein,
the controller matches speeds, heights, and tilt values of the plurality of blotters with an amount of residual ink absorbed by the wiper to predict a replacement cycle of a head pack including the inkjet heads.

19. An electronic apparatus, comprising:
a display device which displays an image and includes a substrate and a pattern formed on the substrate by inkjet heads; and
a processor which transmits an image data signal and an input control signal to the display device,
wherein the inkjet heads are maintained by a maintenance system,
wherein the maintenance system comprises:
a wiper which absorbs residual ink remaining on nozzle surfaces of the inkjet heads;
a plurality of blotters which presses the wiper against the nozzle surfaces; and
a controller which periodically performs position compensation of the plurality of blotters in a direction to reduce a gap deviation between the inkjet heads and the plurality of blotters.

20. The electronic apparatus of claim 19, wherein,
the maintenance system further comprises at least one selected from a first sensor which acquires an image of coating films on the nozzle surfaces of the inkjet heads and a second sensor which acquires an image of the wiper, and
the controller adjusts a gap between the inkjet heads and the plurality of blotters based on at least one selected from the image of the coating films on the nozzle surfaces of the inkjet heads and the image of the wiper.
